(19) United States
(12) Patent Application Publication
(10) Pub. No.: US 2024/0332897 A1
(43) Pub. Date: Oct. 3, 2024

(54) SEMICONDUCTOR LASER

(71) Applicant: Lumentum Operations LLC, San Jose, CA (US)

(72) Inventor: Atsushi NAKAMURA, Komoro (JP)

(21) Appl. No.: 18/477,423

(22) Filed: Sep. 28, 2023

(30) Foreign Application Priority Data
Mar. 30, 2023 (JP) 2023-054497
Jun. 22, 2023 (JP) 2023-102675

(51) Int. Cl. H01S 5/12; H01S 5/028; H01S 5/125

(52) U.S. Cl. CPC H01S 5/1206; H01S 5/028; H01S 5/1237; H01S 5/124; H01S 5/125; H01S 5/0421; H01S 5/34

(57) ABSTRACT

To obtain both a high power and a single mode oscillation of a semiconductor laser, the semiconductor laser includes a diffraction grating layer. The diffraction grating layer includes a λ/4 phase shift portion, and includes first and second regions. The first region has a diffraction pattern arranged therein, the diffraction pattern being formed to reflect a light beam having a Bragg wavelength and having first and second refractive index regions alternately arranged therein. The second region is provided with a first portion that reflects the light beam having the Bragg wavelength in the first region and a second portion that transmits the Bragg wavelength in the first region. The second portion is formed of the first and second refractive index regions. A total length of the first portion in a direction in which the diffraction grating layer extends is shorter than a length of the first region.

### CROSS-REFERENCE TO RELATED APPLICATIONS

The present application claims priority from Japanese Patent Application Number 2023-102675 filed on Jun. 22, 2023 and from Japanese Patent Application Number 2023-054497 filed on Mar. 30, 2023, the contents of which are hereby incorporated by reference into this application.

### TECHNICAL FIELD

The present disclosure relates generally to a semiconductor laser.

### BACKGROUND

Semiconductor lasers are widely used as a light source in optical communications. A distributed feedback semiconductor laser (DFB laser) is one type of a semiconductor laser. The DFB laser can include a diffraction grating. Further, the DFB can include a structure in which the diffraction grating is provided that has a phase shift portion in order to improve characteristics. When an anti-reflection film (or a low-reflection film) is formed on both facets of a semiconductor laser and a λ/4 shift portion is arranged in the diffraction grating, a stable single-wavelength operation can be obtained. In some cases, a reflectance with respect to a light beam having a Bragg wavelength is changed between before and after the phase shift portion, to thereby increase output from one of the facets.

Additionally, a portion of the diffraction grating can be removed from a uniform diffraction grating structure at a constant period in order to adjust a coupling coefficient κ.

### SUMMARY

A diffraction grating structure can be formed by alternately arranging portions of layers having different refractive indices. For example, a diffraction grating structure can be formed by providing irregularities at an interface between an n-type InP substrate and an n-type InGaAsP waveguide layer. Further, in a floating type diffraction grating, a diffraction grating structure can be formed by periodically arranging, between portions of a cladding layer, portions of a layer (high refractive index layer) having a refractive index higher than that of the cladding layer. When a λ/4 phase shift portion is provided, a phase of light reflected in a region at which the refractive index is changed shifts by π, thereby achieving single mode oscillation.

In a structure in which a uniform diffraction grating is provided on one side of a phase shift portion and portions of a diffraction grating on the opposite side are thinned out in order to adjust κ, there is a possibility that it may not oscillate in single mode. In order to obtain a single mode oscillation, a uniform diffraction grating region and a region in which portions of the diffraction grating are thinned out are required to exhibit a same wavelength at which a high reflectance is obtained. When the wavelength at which a high reflectance is obtained differs, reflection at a desired wavelength fails, thereby preventing oscillation in the single mode. In regard to an average refractive index of the uniform diffraction grating region, portions of a cladding layer and portions of a high refractive index layer can be provided with a same width, while fewer portions of the high refractive index layer are provided in a region in which portions of the diffraction grating are thinned out. Thus, the average refractive index differs between the uniform diffraction grating region and the region in which portions of the diffraction grating are thinned out, and the wavelength at which a high reflectance is obtained, which is determined based on the average refractive index and a diffraction grating period, differs therebetween. As a result, the single mode oscillation is not obtained.

Even when the diffraction grating period or the like of the region in which portions of the diffraction grating are thinned out is adjusted so that both the regions exhibit the same wavelength at which a high reflectance is obtained, an injected current density differs depending on presence or absence of portions of the diffraction grating, and, also, fluctuations in carrier density and a temperature rise due to an injected current difference between both the regions depending on the amount of the injected current. This causes an amount of change in refractive index to differ between both the regions. Accordingly, it is difficult to maintain a stable single mode oscillation over a wide range of operating conditions.

Some implementations described herein include a semiconductor laser that achieves both a high power and a single mode oscillation.

In some implementations, the semiconductor laser includes: a substrate; an active layer formed above the substrate; a diffraction grating layer which includes a λ/4 phase shift portion, and includes a first region between a first end portion and the λ/4 phase shift portion and a second region between a second end portion on a side opposite to the first end portion and the λ/4 phase shift portion; and a first electrode and a second electrode that are each common to the first region and the second region, wherein the first region has a diffraction pattern arranged therein, the diffraction pattern being formed to reflect a light beam having a Bragg wavelength and having a first refractive index region and a second refractive index region alternately arranged therein, wherein the second region is provided with one or more first portions including the diffraction pattern to reflect the light beam having the Bragg wavelength in the first region and one or more second portions that transmit the light beam having the Bragg wavelength in the first region, wherein the one or more second portions are formed of the first refractive index region and the second refractive index region, and wherein a total length of the one or more first portions in a direction in which the diffraction grating layer extends is shorter than a length of the first region.

### BRIEF DESCRIPTION OF THE DRAWINGS

FIG. 1 is an example of a top view for illustrating a semiconductor laser according to a first example implementation of the present invention.

FIG. 2 is a schematic sectional view for illustrating the semiconductor laser of FIG. 1 taken along the line II-II.

FIG. 3 is a schematic sectional view for illustrating the semiconductor laser of FIG. 1 taken along the line III-III.

FIG. 4 is a schematic sectional view for illustrating a semiconductor laser according to Modification Example 1 of the first example implementation taken along the line II-II.

FIG. 5 is a schematic sectional view for illustrating a semiconductor laser according to Modification Example 2 of the first example implementation taken along the line II-II.

FIG. 6 is a schematic sectional view for illustrating a semiconductor laser according to Modification Example 3 of the first example implementation taken along the line II-II.

FIG. 7 is a schematic sectional view for illustrating a semiconductor laser according to Modification Example 4 of the first example implementation taken along the line II-II.

FIG. 8 is an example of a top view for illustrating a semiconductor laser according to a second example implementation of the present invention.

FIG. 9 is a schematic sectional view for illustrating a semiconductor laser according to a third example implementation of the present invention taken along a mesa structure.

FIG. 10 is an example of a top view for illustrating a semiconductor laser according to a fourth example implementation of the present invention.

FIG. 11 is a schematic sectional view for illustrating a semiconductor laser according to a fifth example implementation of the present invention taken along a mesa structure.

### DETAILED DESCRIPTION

Embodiments of the present invention are specifically described in detail in the following with reference to the attached drawings. Throughout the figures for illustrating the embodiments, like reference numerals are used to represent members having like functions, and a repeated description thereof is omitted. The drawings referred to in the following are only for illustrating the embodiments by way of examples, and are not necessarily drawn to scale.

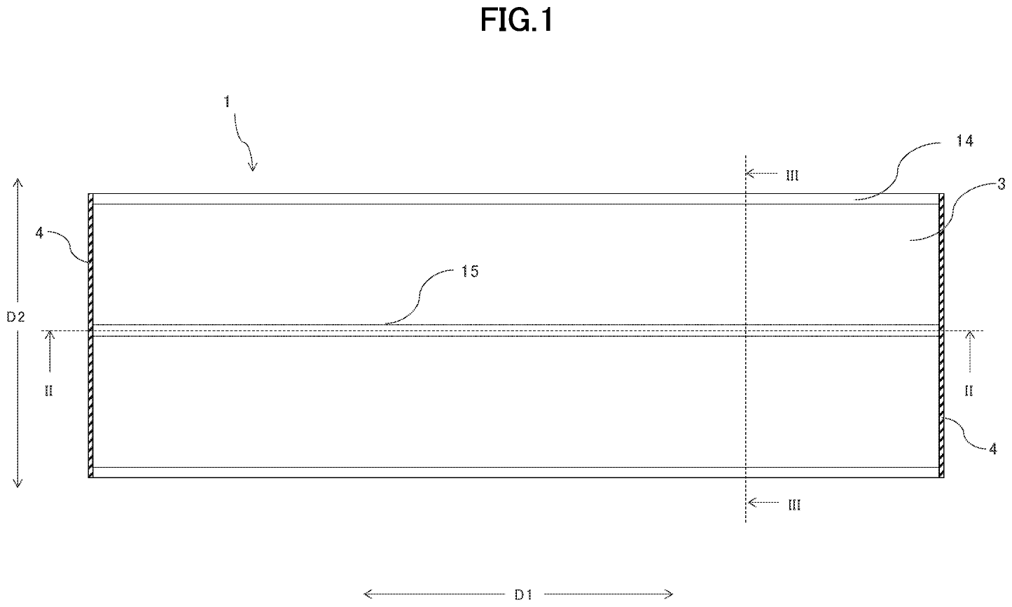

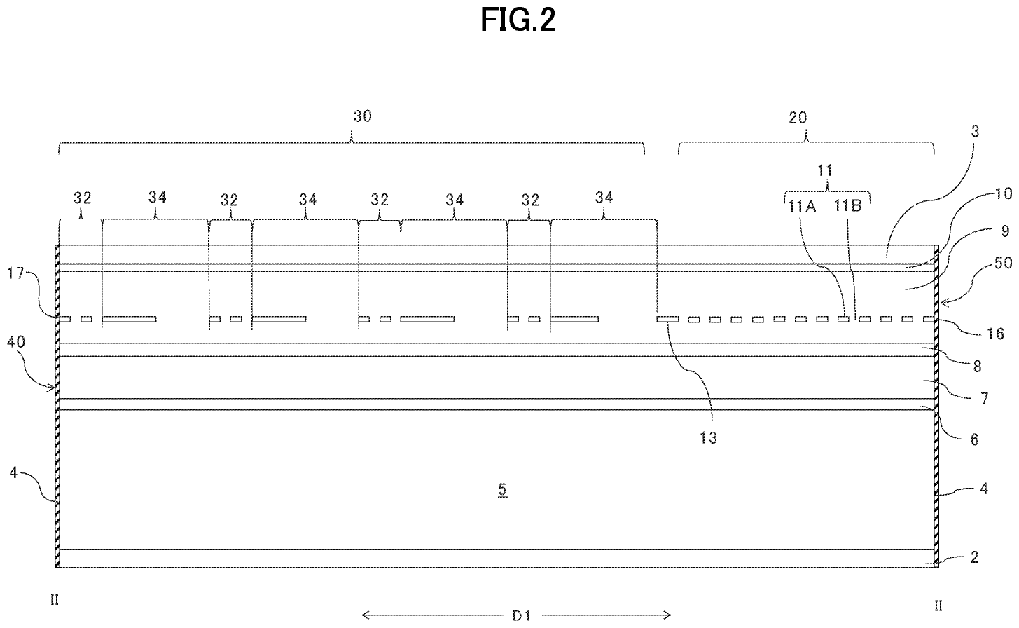

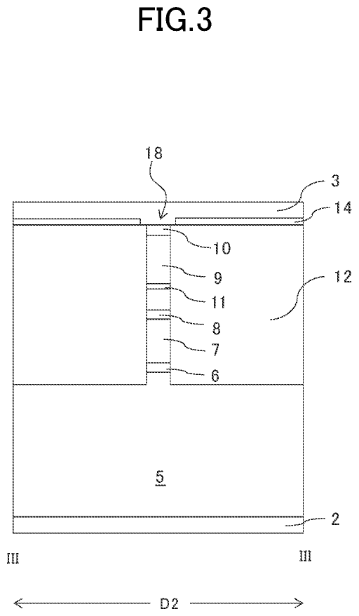

FIG. 1 is a top view of a semiconductor laser 1 according to a first example implementation of the present invention. FIG. 2 shows a schematic sectional view taken along the line II-II of FIG. 1. FIG. 3 shows a schematic sectional view taken along the line III-III of FIG. 1. The semiconductor laser 1 may include a first electrode 2 on a back surface thereof and a second electrode 3 on a front surface thereof. The first electrode 2 may be provided below a substrate 5 in common to a first region 20 (described later) and a second region 30 (described later). The second electrode 3 may be provided above a diffraction grating layer 11 (described later) in common to the first region 20 and the second region 30. The first electrode 2 and the second electrode 3 may be metal layers. A light beam may be emitted from a front facet 40 (facet on the left side of FIG. 1) through injection of a current between the first electrode 2 and the second electrode 3. A low-reflection facet coating film 4 may be formed on the front facet 40 and a back facet 50 (facet on the right side of FIG. 1).

In the semiconductor laser 1, semiconductor layers may be formed in the stated order of a first conductivity type optical confinement layer (SCH layer) 6, an active layer 7, a second conductivity type optical confinement layer (SCH layer) 8, a second conductivity type cladding layer 9, and a second conductivity type contact layer 10 on the substrate 5 of the first conductivity type. Further, the second conductivity type cladding layer 9 may have the diffraction grating layer 11 formed therein. The semiconductor laser 1 may be a DFB laser. The active layer 7 may be formed of, for example, a multiple-quantum well layer. Further, the multiple-quantum well layer may be an intrinsic semiconductor or an n-type semiconductor. In this case, the first conductivity type may be an n-type and the second conductivity type may be a p-type, but the first conductivity type may be the p-type and the second conductivity type may be the n-type. Further, the semiconductor layers described above may have a mesa structure 15. The mesa structure 15 may extend in a light extraction direction (first direction D1). A lower portion of the mesa structure 15 may be a part of the substrate 5. Both sides of the mesa structure 15 may be covered with a semi-insulating buried layer 12. The buried layer 12 may be a stack formed of semiconductor layers of the p-type and the n-type. The dotted line of FIG. 1 indicates a position of a boundary between an upper portion of the mesa structure 15 and the buried layer 12.

The semiconductor laser 1 may have an insulating film 14 on the buried layer 12. The insulating film 14 may cover the front surface of the semiconductor laser 1 (e.g., except for a part thereof). The insulating film 14 may include an opening (through-hole) 18 in a region corresponding to the upper portion of the mesa structure 15. In the through-hole 18, the second electrode 3 and the second conductivity type contact layer 10 may be connected, and an electric signal may be applied to the mesa structure 15 (a current may be injected). In this case, the through-hole 18 may be formed along the first direction D1. Further, in a second direction D2 perpendicular to the first direction D1, the through-hole 18 may have a width larger than a width of the mesa structure 15. However, both may have the same width.

The diffraction grating layer 11 may be of a floating type, and may be formed of the second conductivity type cladding layer 9 and regions having a refractive index different from that of the second conductivity type cladding layer 9. The refractive index of the regions having the refractive index different from that of the second conductivity type cladding layer 9 may be hereinafter referred to as “first refractive index,” and the refractive index of the second conductivity type cladding layer 9 may be hereinafter referred to as “second refractive index.” In this case, the first refractive index may be higher than (e.g., greater than) the second refractive index. However, a relationship between the refractive indices may be reversed. The diffraction grating layer 11 may include a phase shift portion 13 having a partially different diffraction grating interval. In this case, the phase shift portion 13 may be a λ/4 phase shift portion.

The diffraction grating layer 11 may have the first region 20 between a first end portion 16 and the phase shift portion 13. In the first region 20, the diffraction grating layer 11 may be formed by alternately arranging a first refractive index region 11A and a second refractive index region 11B that may have the same length in a direction in which the diffraction grating layer 11 extends. That is, a diffraction pattern that reflects a light beam having a Bragg wavelength may be arranged in the first region 20. In this case, the diffraction grating layer 11 may have a diffraction grating period set so as to oscillate a wavelength of a 1.3 micrometers (μm) band or a 1.55 μm band. However, another wavelength band may be used. As the phase shift portion 13, two first refractive index regions 11A may be continuously arranged, but the present invention is not limited thereto, and two second refractive index regions 11B may be continuously arranged.

The diffraction grating layer 11 may have the second region 30 between the phase shift portion 13 and a second end portion 17. The second region 30 may include one or more first portions 32 including a diffraction pattern and having a period corresponding to the Bragg wavelength of the first region 20 and one or more second portions 34 that hardly reflect the light beam having the Bragg wavelength. The one or more first portions 32 may each be formed by alternately arranging the first refractive index region 11A and the second refractive index region 11B that have the same length and period as those in the first region 20 such that the phase shifts by 7L from the phase of the diffraction grating in the first region 20. In this case, the same length means the length of the first refractive index region 11A in the first direction D1 and the length of the second refractive index region 11B in the first direction D1. Each second portion 34 may be formed by alternately arranging the first refractive index region 11A and the second refractive index region 11B such that one of a front end or a back end of the first refractive index region 11A may be located at a position different from a periodic position of the one of the front end or the back end of the first refractive index region 11A in the first portion 32.

In other words, the second region 30 may have the one or more second portions 34 arranged between a plurality of first portions. Each second portion 34 may have the first refractive index region 11A and the second refractive index region 11B, and widths and intervals of both the regions in a direction along the first direction D1 differ so as to suppress high-order scattering of diffracted light with respect to a desired wavelength (Bragg wavelength). The second portion 34 may be provided with the first refractive index region 11A and the second refractive index region 11B so as not to reflect (i.e., so as to transmit) the Bragg wavelength.

A coupling coefficient κ of a semiconductor laser depends on a semiconductor multilayer structure. In the first example implementation, the first region 20 and the second region 30 may have the same semiconductor multilayer structure except for an arrangement layout of the first refractive index regions 11A and the second refractive index regions 11B of the diffraction grating layer 11. The first region 20 and the first portion 32 of the second region 30 may have the same diffraction grating period, and thus may have the same coupling coefficient κ. Meanwhile, the second portion 34 of the second region 30 may transmit the light beam having the Bragg wavelength in the first region 20 and the first portion 32, and hence the coupling coefficient may be regarded as zero. In an example, some light reflection (scattering) may occur, but there is almost no influence on wavelength selectivity, and the coupling coefficient can be substantially regarded as zero. In this case, when a length of the first region 20 in the first direction D1 is represented by L1, a normalized coupling coefficient of the first region 20 is κ×L1. Meanwhile, when a total length of the first portions 32 of the second region 30 in the first direction D1 is represented by L2, a normalized coupling coefficient of the entire second region 30 is κ×L2. The second region 30 may include the second portion 34 but may be practically a transmissive region for the Bragg wavelength as described above, and thus may not contribute to the reflection of light or exert an influence on the normalized coupling coefficient. When L1 is set longer than L2, intensity of light output from the front facet 40 becomes higher than intensity of light output from the back facet 50. The terms “front” and “back” may be used herein for the sake of convenience, and a facet having the larger light output may be referred to as “front facet.” In general optical communications, the higher light intensity may be preferred, and the light output from the front facet may be used for communications.

In this case, an average refractive index between the first end portion 16 and the λ/4 phase shift portion and an average refractive index between the second end portion 17 and the λ/4 phase shift portion may be substantially the same. In other words, the average refractive indices of the first region 20 and the second region 30 may be substantially the same. The average refractive indices of the first portions 32 and the second portions 34 of the second region 30 may be also substantially the same. While the first portions 32 and the second portions 34 may be obtained as a plurality of regions through division, each average refractive index may be considered to be an overall average refractive index of all the plurality of regions. The average refractive index means a refractive index that takes the length of each portion into consideration. For example, the average refractive index of the second region 30 may be obtained by summing up a product of the total length of the first portions 32 and the refractive index and a product of a total length of the second portions 34 and the refractive index and dividing the obtained sum by a total sum of the lengths of the first portions 32 and the second portions 34. Further, when a stripe width and the current density are the same, a relative phase relationship of the diffraction grating between the first region 20 and the first portions 32 of the second region 30 may be maintained irrespective of a magnitude of a drive current and an environmental temperature. That is, a phase of a light beam reflected in the first portion 32 shifts by π from the phase of a light beam propagating through the first region 20, and it may be possible to achieve a single mode oscillation. In other words, even in the first portion 32, a high reflectance may be obtained with respect to the light beam having the Bragg wavelength, which may be reflected by the first region 20. Accordingly, a single mode oscillation may be obtained. The average refractive indices of the first region 20 and the second region 30 may be desired to be exactly the same, but do not always become exactly the same due to manufacturing variations or the like. However, even without exactly the same average refractive indices, when an average refractive index difference between three parts, that is, the first region 20, the first portions 32, and the second portions 34 is within 0.5%, a single mode oscillation may be achieved. In other words, when a difference between a maximum average refractive index and a minimum average refractive index among the average refractive indices of the first region 20, the first portions 32, and the second portions 34 is within 0.5%, a single mode oscillation may be obtained. In the first example implementation, the diffraction grating layer 11 extending over the first region 20 and the second region 30 may comprise the same material and formed in the same thickness. Thus, the difference in average refractive index may be proportional to a difference in ratio (opening ratio) between the area of the first refractive index regions 11A and the area of the second refractive index regions 11B. In order to cause the average refractive index difference to fall within 0.5%, a difference in area ratio may be required to be set to 20% or less. That is, a difference in ratio (opening ratio) between the area of the first refractive index regions 11A and the area of the second refractive index regions 11B among the first region 20, the first portions 32, and the second portions 34 may be within 20%. Further, a difference in ratio between the area of the first refractive index regions 11A and the area of the second refractive index regions 11B between the first region 20 and the second region 30 may be within 20%. In this case, as illustrated in FIG. 2, the first electrode 2 may be provided below the substrate 5 in common to the first region 20 and the second region 30. The second electrode 3 may be provided above the diffraction grating layer 11 in common to the first region 20 and the second region 30. The first electrode 2 and the second electrode 3 may be arranged over both the first region 20 and the second region 30, and both may have the same current injected therein. Accordingly, the first region 20 and the second region 30 may have substantially the same current density and temperature, and the effects of the present invention may be obtained. As long as the first region 20 and the second region 30 have the same injected current density, the second electrode 3 may be divided into two.

As a comparative example, each entire second portion 34 may be formed of the second refractive index region 11B. In the case of only the second refractive index region 11B, the average refractive index of second portions 34 may differ from the average refractive indices of the first region 20 and the first portions 32. Thus, when the average refractive indices of the first portions 32 and the second portions 34 are the same, even when the diffraction grating is arranged so as to cause the phases of the first region 20 and the first portions 32 to shift by π, a diffraction grating phase shift that takes optical path lengths of the first region 20 and the first portions 32 into consideration is no longer a π-shift. As a result, the single mode oscillation may not be obtained. When the single mode oscillation is not obtained, a side mode suppression ratio may be reduced, which may not be preferred as a semiconductor laser for optical communications. The same applies to a case in which each entire second portion 34 is formed of the first refractive index region 11A. Accordingly, in a structure in which the first refractive index regions 11A are thinned out in order to increase the light output from the front facet 40 by reducing κ, a single mode oscillation cannot be maintained.

In contrast, in the first example implementation, the area ratio between the first refractive index regions 11A and the second refractive index regions 11B in the second portion 34 may be substantially the same as the area ratio therebetween in each of the first portion 32 and the first region 20. Thus, the average refractive index of the second portions 34 may be the same as that of the first regions 20, and diffraction grating phases that take the optical path lengths of the first region 20 and the first portions 32 into consideration may have a π-shift relationship, thereby allowing a single mode oscillation to be maintained. Further, the normalized coupling coefficient of the second region 30 may be set smaller than that of the first region 20, and hence the light output from the front facet 40 may be increased. The first refractive index regions 11A and second refractive index regions 11B illustrated in FIG. 2 do not indicate actual dimensions. For example, in a case of a semiconductor laser of a 1.3 μm band, a period (a total length of one first refractive index region 11A and one second refractive index region 11B) of the diffraction grating layer 11 in the first region 20 may be about 200 nm. A length of the semiconductor laser in the first direction D1 may be, for example, 500 μm. That is, while a diffraction grating structure corresponding to two periods may be drawn for the first portion 32 in FIG. 2, in some implementations, more first refractive index regions 11A and more second refractive index regions 11B may be arranged. Further, the diffraction grating layer 11 may be arranged below the first conductivity type SCH layer (first conductivity type optical confinement layer 6).

The first region 20 and the second region 30 may be defined herein as starting at the facets of the semiconductor laser 1, but may be strictly defined as starting at end portions of the diffraction grating layer 11. That is, in the first example implementation, the first region 20 may be defined as extending from the end portion (first end portion 16) of the diffraction grating layer 11 on the back side to the phase shift portion 13, and the second region 30 may be defined as extending from the phase shift portion 13 to the end portion (second end portion 17) of the diffraction grating layer 11 on the front side. In the first example implementation, the end portions of the diffraction grating layer 11 may be positioned at substantially the same position as the front facet 40 or the back facet 50. Further, in the first example implementation, the length of the first region 20 in the first direction D1 may be shorter than the length of the second region 30 in the first direction D1. That is, the phase shift portion 13 may be arranged on a back side of the entire diffraction grating layer 11. However, the present invention is not limited thereto, and the phase shift portion 13 may be positioned in a central portion of the diffraction grating layer 11 or on a front side thereof.

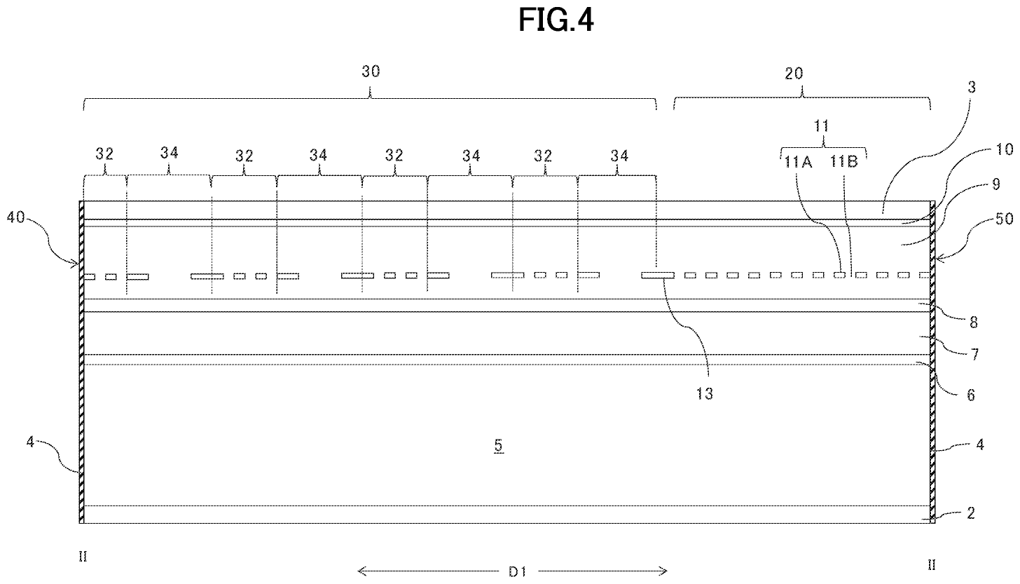

FIG. 4 is a schematic sectional view for illustrating the semiconductor laser 1 according to Modification Example 1 of the first example implementation taken along the line II-II. The second portion 34 may be formed of a first refractive index region 11A, a second refractive index region 11B, and a first refractive index region 11A. The area ratio between the total area of the two first refractive index regions 11A and the area of the one second refractive index region 11B may be substantially the same as the area ratio therebetween in each of the first portion 32 and the first region 20. Further, in regard to intervals of the first refractive index region 11A and first refractive index region 11A and the second refractive index region 11B in the second portion 34, an opening may be provided such that widths and intervals of the respective regions differ so as to suppress high-order scattering. With this configuration as well, a single mode oscillation may be achieved.

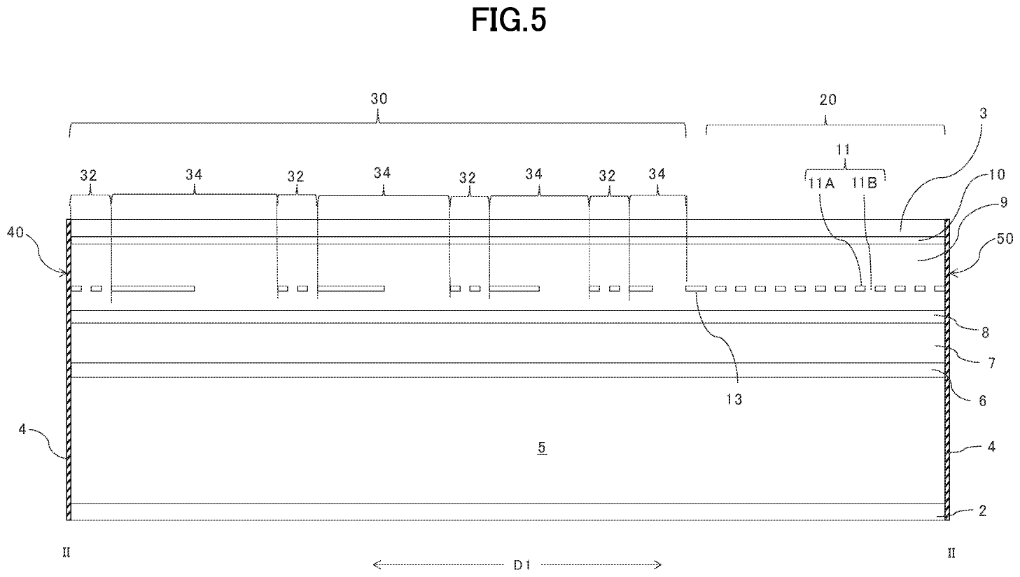

FIG. 5 is a schematic sectional view for illustrating the semiconductor laser 1 according to Modification Example 2 of the first example implementation taken along the line II-II. The semiconductor laser 1 may have a plurality of second portions 34, and lengths thereof in the first direction D1 differ from one another. From the viewpoint of each second portion 34, the area ratio between the first refractive index regions 11A and the second refractive index regions 11B may be substantially the same as the area ratio therebetween in each of the first portion 32 and the first region 20. Unlike in the first example implementation or Modification Example 1, the lengths of the first refractive index regions 11A and the second refractive index regions 11B in the first direction D1, which may be included in the respective second portions 34, differ from one another. When the second portions 34 are arranged at a constant period, light corresponding to the period may be reflected and scattered, and an influence on the light output intensity becomes larger. In Modification Example 2, the second portions 34 may not be periodically arranged, and hence it may be possible to suppress such an influence and maintain high output under a wide range of conditions.

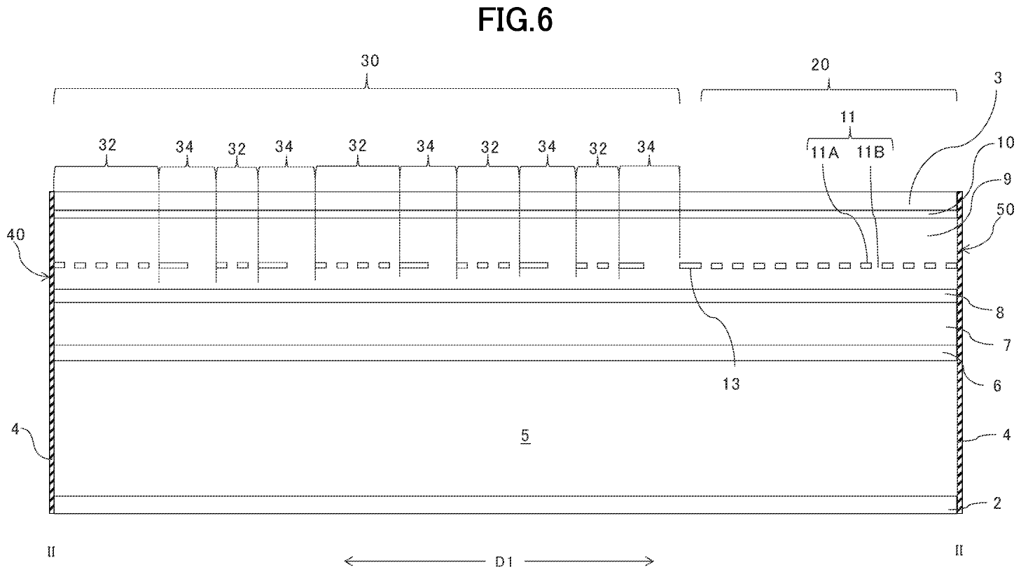

FIG. 6 is a schematic sectional view for illustrating the semiconductor laser 1 according to Modification Example 3 of the first example implementation taken along the line II-II. The semiconductor laser 1 may have a plurality of first portions 32, and lengths thereof in the first direction D1 that differ from one another. The normalized coupling coefficient of the second region 30 may be determined by the total length of the first portions 32 arranged at the same period as that of the diffraction grating layer 11 in the first region 20 and at the phase shifting by 7E from the phase of the diffraction grating in the first region 20. For that reason, the plurality of first portions 32 may not be required to have the same length. Modification Example 2 and Modification Example 3 may be combined. That is, as long as the area ratio between the first refractive index regions 11A and the second refractive index regions 11B in the second portion 34 is substantially the same as the area ratio therebetween in each of the first portion 32 and the first region 20, the first refractive index regions 11A and the second refractive index regions 11B in the second portion 34 may be arranged in any manner. Further, the plurality of first portions 32 may not be required to have the same length in the first direction D1, and as long as the normalized coupling coefficient of the entire second region 30 is smaller than that of the first region 20, the lengths of the plurality of first portions 32 in the first direction D1 may differ from one another. The same applies to the plurality of second portions 34, and the lengths thereof are not required to be the same.

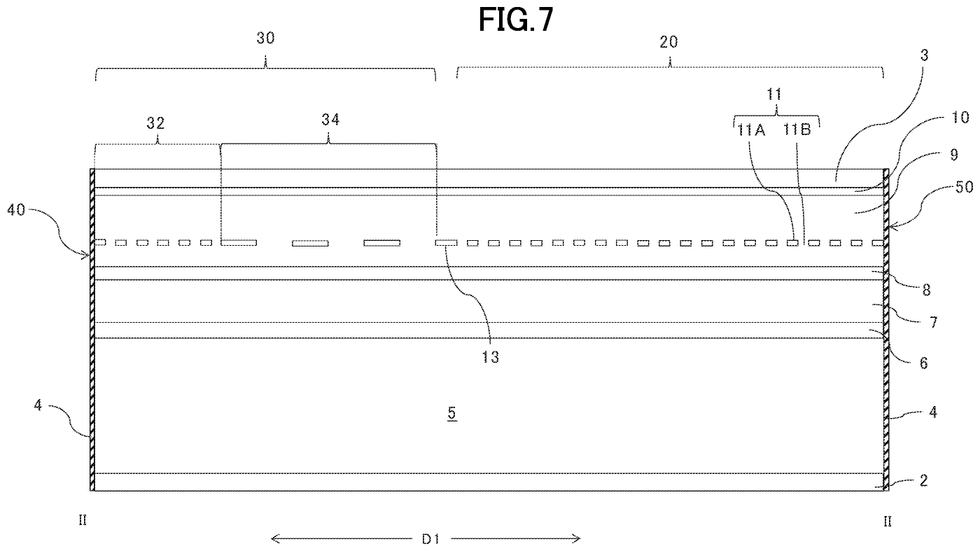

FIG. 7 is a schematic sectional view for illustrating the semiconductor laser 1 according to Modification Example 4 of the first example implementation taken along the line II-II. In Modification Example 4, the second region 30 of the semiconductor laser 1 has one first portion 32 and one second portion 34. The normalized coupling coefficient of the second region 30 may be a product of the coupling coefficient κ and the length of the first portion 32 in the first direction D1. This normalized coupling coefficient may be smaller than the normalized coupling coefficient of the first region 20. In other words, the length of the first region 20 in the first direction D1 may be longer than the length of the first portion 32 of the second region 30. As described above, it is not required to arrange a plurality of first portions 32. However, the length of the second portion 34 in the first direction D1 may be preferred to be set equal to or smaller than half the length of the first region 20. When the length of the second portion 34 is larger than half the length of the first region 20, oscillations at a wavelength different from a desired Bragg wavelength may be observed. When a plurality of second portions 34 are included, the length of each second portion 34 may be equal to or smaller than half the length of the first region 20, and the total length of the plurality of second portions 34 may be larger than that of the first region 20.

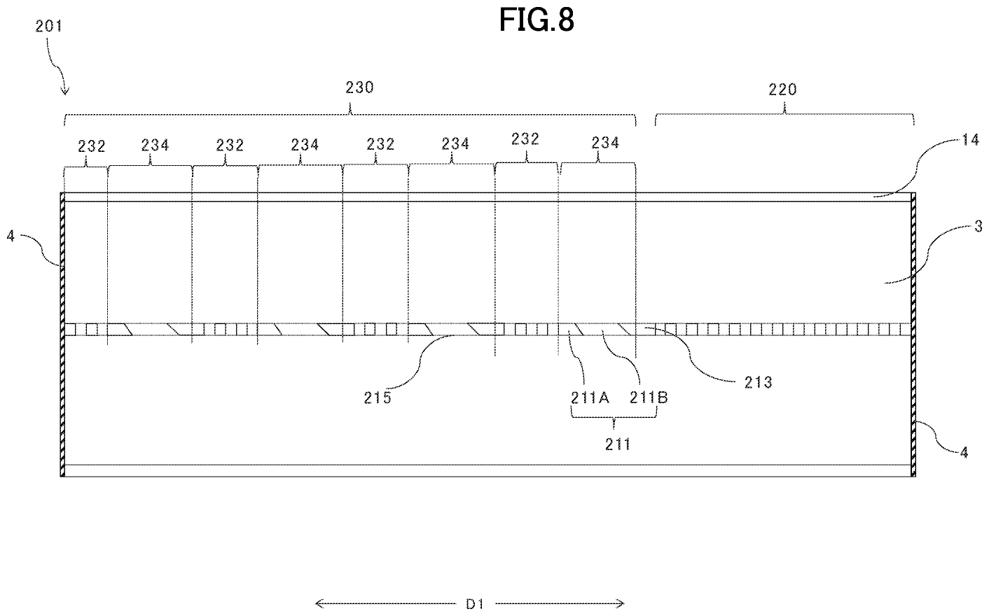

FIG. 8 is a top view for illustrating a semiconductor laser 201 according to a second example implementation of the present invention. In FIG. 8, a diffraction grating layer 211 is illustrated for the sake of description. An arrangement of the diffraction grating layer 211 may be the same as the structure described in the first example implementation, in particular, Modification Example 1. There may be a feature in that an interface between a first refractive index region 211A and a second refractive index region 211B in a second portion 234 may be inclined with respect to the first direction D1. In the second portion 234 as well, the interface between the first refractive index region 211A and the second refractive index region 211B may form a change point of the refractive index, and may form a reflection point. When a light beam reflected by the diffraction grating and a light beam reflected at the interface between the first refractive index region 211A and the second refractive index region 211B in the second portion 234 are out of phase with each other, this causes the lower SMSR. In view of this, a reflecting portion may be inclined with respect to a direction in which a light beam propagates, thereby being capable of reducing reflection and achieving a single mode oscillation.

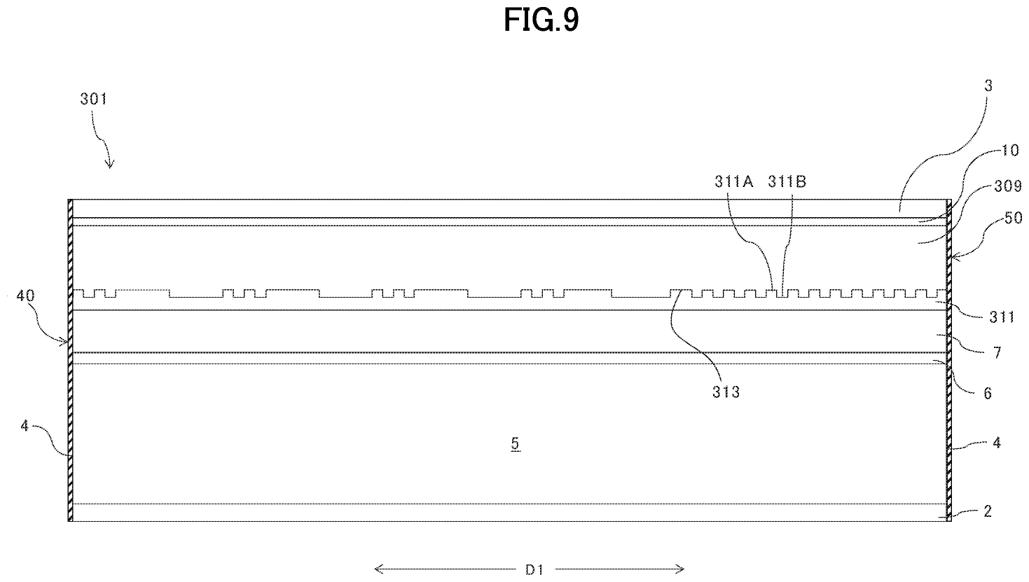

FIG. 9 is a schematic sectional view (corresponding to FIG. 2) of a semiconductor laser 301 according to a third example implementation of the present invention along a mesa structure. In the semiconductor laser 301, a second conductivity type SCH layer 311 may have a diffraction grating structure. In other words, the second conductivity type SCH layer 311 may have two functions of optical confinement and a diffraction grating. The diffraction grating may have recessed portions formed of a second conductivity type cladding layer 309. Protruding portions of the second conductivity type SCH layer 311 may serve as first refractive index regions 311A, and regions of the second conductivity type cladding layer 309 surrounded by the protruding portions may serve as second refractive index regions 311B. The semiconductor laser 301 may have the diffraction grating layer 311 (second conductivity type SCH layer 311) arranged in the same manner as in the first example implementation, and may have a high power and a single mode oscillation. The diffraction grating structure may be arranged in a layer below the first conductivity type SCH layer (first conductivity type optical confinement layer 6) (on a side in contact with the substrate 5).

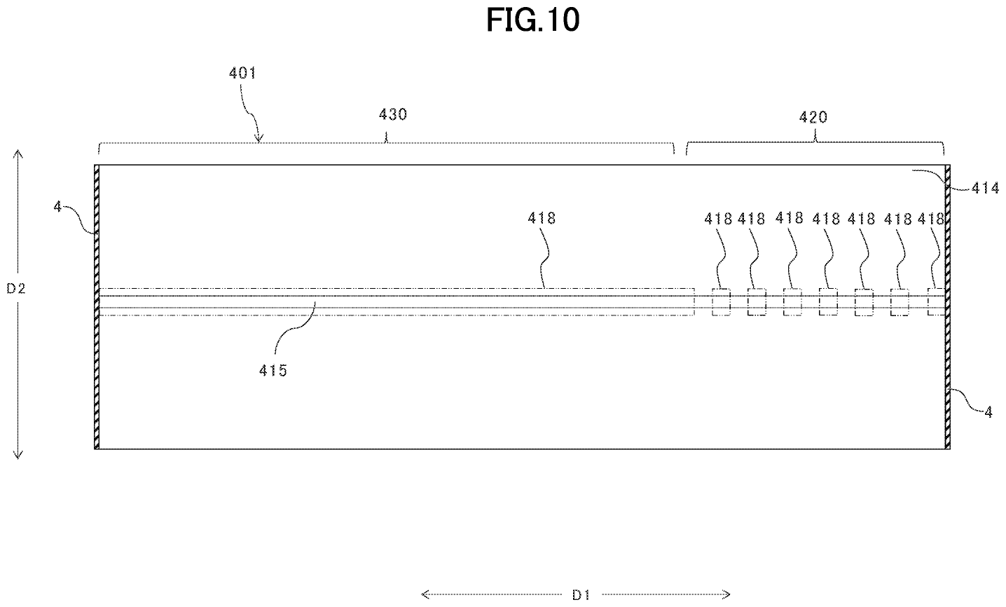

FIG. 10 is a top view for illustrating a semiconductor laser 401 according to a fourth example implementation of the present invention. The semiconductor laser 401 may have the same structure as that of the semiconductor laser 1 according to the first example implementation except for shapes of through-holes 418. In FIG. 10, for the sake of description, a mesa structure 415 may be indicated by the broken lines, and the through-holes 418 may be indicated by the two-dot chain lines. Further, the second electrode 3 is not shown.

The through-holes 418 may be openings formed in an insulating film 414. The through-holes 418 may not be arranged on parts of an upper surface of the mesa structure 415 in a first region 420. In other words, the insulating film 414 may be arranged on the parts of the upper surface of the mesa structure 415 in the first region 420. The through-hole 418 may be formed throughout a second region 430. The second electrode 3 may cover the entire through-holes 418.

As described above in the first example implementation, the normalized coupling coefficient of the first region 420 may be larger than the normalized coupling coefficient of the second region 430. Further, a boundary between the first region 420 and the second region 430, that is, the phase shift portion 13 (not shown in FIG. 10) may be arranged on a back side (right side of FIG. 10) of the semiconductor laser 401 relative to the central portion. For that reason, a photon density of the first region 420 may be lower than a photon density of the second region 430. Consumption of carriers due to stimulated emission increases as the photon density increases, and hence when the first region 420 and the second region 430 have the same injected current density, a carrier density of the first region 420 may be higher than a carrier density of the second region 430. An increase in carrier density may be a factor that degrades characteristics of the semiconductor laser, for example, a relative noise intensity characteristic. The carrier density depends on an amount of the injected current. In view of this, in the fourth example implementation, in the first region 420, a limitation may be imposed on a region into which the current may be injected, to thereby reduce an increase in carrier density. In order to limit the region into which the current is injected, there may be provided a structure in which the through-holes 418 in the first region 420 are not arranged on parts of the upper surface of the mesa structure 415 instead of being formed on the entire upper surface. In other words, the upper surface of the mesa structure 415 in the first region 420 may have an opening portion (through-hole 418) and a non-opening portion (insulating film 414) alternately arranged along the first direction D1. A current may not be injected into a region in which the non-opening portion (insulating film 414) may be arranged, thereby being capable of reducing the carrier density of the entire first region 420.

A ratio of the formed opening portions to the entire first region 420 may be preferred to be 60% or less, and may be further preferred to be 50% or less and 20% or more.

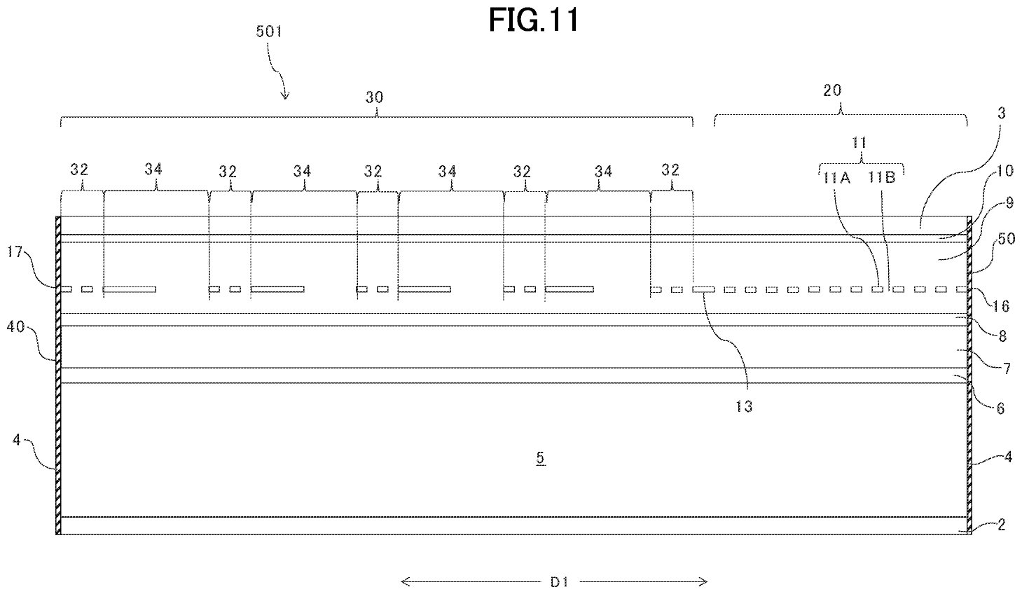

FIG. 11 is a schematic sectional view (corresponding to FIG. 2) of a semiconductor laser 501 according to a fifth example implementation of the present invention along a mesa structure. The fifth example implementation differs from the first example implementation in that the first portion 32 of the second region 30 of the semiconductor laser 501 may be arranged continuously with the phase shift portion 13. In this manner, the second portion 34 may not be required to be arranged in the second region 30 on a side thereof in contact with the phase shift portion 13.

The present invention may not be limited to the embodiments described above, and various modifications may be made thereto. For example, the configurations described in the embodiments may be replaced by substantially the same configuration, a configuration having the same action and effect, and a configuration which may achieve the same object. Further, the present invention may not be limited to a buried type semiconductor laser, and may be applied even to a ridge waveguide semiconductor laser. The semiconductor laser may be a CW light source or may be a direct-modulation semiconductor laser.

The present invention achieves both a high power and a single mode oscillation in a DFB laser having a phase shift portion. Those may be achieved by each example implementation of the present invention formed of the first region and the second region with the λ/4 phase shift portion interposed therebetween, the first region having the diffraction grating structure arranged at a uniform period, the second region including the diffraction grating structure (first portion) arranged at a uniform period and the second portion having the same average refractive index as that of the first portion and having the structure that prevents high-order scattering from occurring with respect to a desired wavelength. The area ratios between the first refractive index regions and the second refractive index regions that may be arranged in the first region, the first portion, and the second portion may be substantially the same. The diffraction grating in the first portion may be arranged such that the phase differs by 7L from the phase of the diffraction grating in the first region 20. More specifically, the diffraction grating structure in the first portion may have the first refractive index region and the second refractive index region arranged in a structure that physically shifts by 7L from the phase of the diffraction grating structure of the first region. The second portion may have the first refractive index region and the second refractive index region while being almost non-reflective regarding the Bragg wavelength at which the first portion and the first region may be highly reflective. The average refractive indices of the first region, the first portion, and the second portion may be substantially the same, and may be preferred to be 0.5% or less. With this structure, reflection occurs in the first portion under a state in which the phase of a light beam shifts by π from the light beam having the Bragg wavelength in the first region, thereby achieving a single mode oscillation. The product of the length L1 of the first region and the normalized coupling coefficient κ in the first region may be larger than the product of the total length L2 of the first portions and the normalized coupling coefficient κ. A plurality of first portions and a plurality of second portions may be arranged. When a plurality of portions are arranged, the first portion and the second portion may be desired to be alternately arranged. The length of the second portion in a direction in which the diffraction grating structure extends may be preferred to be equal to or smaller than half the length of the first region. The lengths of the plurality of second portions in the direction in which the diffraction grating structure extends may differ from one another. The lengths of the plurality of first portions in the direction in which the diffraction grating structure extends may differ from one another. The diffraction grating layer structure may be provided above or below an active layer. The diffraction grating structure may be formed in an optical confinement layer, or may be formed separately from the optical confinement layer. The semiconductor laser may be of a buried type in which a mesa structure is buried by a semiconductor, or may be of a ridge waveguide type in which a mesa structure is not buried by a semiconductor layer. It may be also possible to improve characteristics by reducing the carrier density of the first region. In order to reduce the carrier density, an opening ratio of the through-holes to the first region may be preferred to be 60% or less, and may be further preferred to be 50% or less and 20% or more. The DFB laser according to at least one example implementation of the present invention may oscillate wavelength of a 1.3 μm band or a 1.55 μm band. However, another wavelength band may be used.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor laser, comprising:
a substrate;
an active layer formed above the substrate;
a diffraction grating layer which includes a λ/4 phase shift portion, and includes a first region between a first end portion and the λ/4 phase shift portion and a second region between a second end portion on a side opposite to the first end portion and the λ/4 phase shift portion; and
a first electrode and a second electrode that are each common to the first region and the second region,
wherein the first region has a diffraction pattern arranged therein, the diffraction pattern being formed to reflect a light beam having a Bragg wavelength and having a first refractive index region and a second refractive index region alternately arranged therein,
wherein the second region is provided with one or more first portions including the diffraction pattern to reflect the light beam having the Bragg wavelength in the first region and one or more second portions that transmit the light beam having the Bragg wavelength in the first region,
wherein the one or more second portions are formed of the first refractive index region and the second refractive index region, and
wherein a total length of the one or more first portions in a direction in which the diffraction grating layer extends is shorter than a length of the first region.

2. The semiconductor laser according to claim 1,
wherein the first region has a uniform diffraction grating structure in which the first refractive index region and the second refractive index region are alternately arranged in the direction in which the diffraction grating layer extends,
wherein the one or more first portions of the second region are each formed by alternately arranging the first refractive index region and the second refractive index region that have the same length as a length of the first refractive index region and the second refractive index region in the first region such that a phase shifts by 7E from a phase of a diffraction grating in the first region, and
wherein the one or more second portions of the second region are each formed by alternately arranging the first refractive index region and the second refractive index region such that one of a front end or a back end of the first refractive index region is located at a position different from a periodic position of the one of the front end or the back end of the first refractive index region in the one or more first portions.

3. The semiconductor laser according to claim 1, wherein a difference between an average refractive index between the first end portion and the λ/4 phase shift portion and an average refractive index between the second end portion and the λ/4 phase shift portion is within 0.5%.

4. The semiconductor laser according to claim 1, wherein a normalized coupling coefficient of the first region is larger than a normalized coupling coefficient of the second region.

5. The semiconductor laser according to claim 1, wherein an area ratio between the first refractive index region and the second refractive index region in the first region is substantially the same as an area ratio between the first refractive index region and the second refractive index region in each of the one or more first portions and the one or more second portions.

6. The semiconductor laser according to claim 1, further comprising:
a front facet close to the second end portion; and
a back facet close to the first end portion,
wherein each of the front facet and the back facet has a low-reflection facet coating film formed thereon.

7. The semiconductor laser according to claim 1, wherein the length of the first region in the direction in which the diffraction grating layer extends is shorter than a length of the second region.

8. The semiconductor laser according to claim 1,
wherein lengths of the one or more first portions in the direction in which the diffraction grating layer extends are the same, and
wherein lengths of the one or more second portions in the direction in which the diffraction grating layer extends are the same.

9. The semiconductor laser according to claim 1, wherein lengths of the one or more first portions in the direction in which the diffraction grating layer extends differ from one another.

10. The semiconductor laser according to claim 1, wherein lengths of the one or more second portions in the direction in which the diffraction grating layer extends differ from one another.

11. The semiconductor laser according to claim 1, wherein one of the one or more first portions of the second region is arranged in contact with the phase shift portion.

12. The semiconductor laser according to claim 1, wherein the one or more first portions each include a plurality of the first refractive index regions and a plurality of the second refractive index regions.

13. The semiconductor laser according to claim 1, wherein the one or more second portions are each formed such that, in a plan view, an interface between the first refractive index region and the second refractive index region is inclined with respect to the direction in which the diffraction grating layer extends.

14. The semiconductor laser according to claim 1, further comprising a cladding layer above the active layer,
wherein the first refractive index region of the diffraction grating layer is a layer having a refractive index higher than a refractive index of the cladding layer, and
wherein the second refractive index region of the diffraction grating layer has the same refractive index as the refractive index of the cladding layer.

15. The semiconductor laser according to claim 1, further comprising a through-hole for injecting a current into the active layer.

16. The semiconductor laser according to claim 15, wherein the through-hole is arranged over the first region, the phase shift portion, and the second region.

17. The semiconductor laser according to claim 15, wherein the through-hole is discretely arranged in the first region.

18. The semiconductor laser according to claim 16, wherein the through-hole is arranged in the first region in a region that is 50% or less and 20% or more of the entire first region in a plan view.

19. The semiconductor laser according to claim 1, wherein the second region includes one second portion and,
a length of the second portion in the direction in which the diffraction grating layer extends is equal to or smaller than half the length of the first region.

20. The semiconductor laser according to claim 5, wherein a difference between the area ratio between the first refractive index region and the second refractive index region in the first region and the area ratio between the first refractive index region and the second refractive index region in each of the one or more first portions and the one or more second portions is within 20%.
